(19) United States
(12) Patent Application Publication
(10) Pub. No.: US 2026/0105943 A1
(43) Pub. Date: Apr. 16, 2026

(54) READ AND PROGRAM CIRCUITRY FOR MEMORY CIRCUIT WITH PROTECTION BIT

(71) Applicant: QuickLogic Corporation, San Jose, CA (US)

(72) Inventors: Ket Chong YAP, San Jose, CA (US); Greg Allen MARTIN, Austin, TX (US); Wilma Wai-Man SHIAO, San Jose, CA (US); Chih Hung LIAO, Fremont, CA (US); Andrew Robert LUKEFAHR, Bloomington, IN (US)

(73) Assignee: QuickLogic Corporation, San Jose, CA (US)

(21) Appl. No.: 19/312,039

(22) Filed: Aug. 27, 2025

Related U.S. Application Data
(60) Provisional application No. 63/707,877, filed on Oct. 16, 2024.

(51) Int. Cl. G11C 11/16

(52) U.S. Cl. CPC G11C 11/1657; G11C 11/1655; G11C 11/1673

(57) ABSTRACT

The present disclosure relates to a system of integrated circuits, such as field programmable gate arrays (FPGAs), that includes a plurality of configuration bits and a protection bit. Each integrated circuit includes a programmable logic device with magnetoresistive memory circuitry capable of consistent, reliable operation in radiation rich environments. The plurality of configuration bits and one protection bit are each coupled to a respective bit line. Each configuration bit includes a first and second plurality of logic components coupled to one another and to the respective bit line and a magnetoresistive memory circuit coupled between the first plurality of logic components and the second plurality of logic components. Each protection bit includes the first plurality of logic components coupled to the magnetoresistive memory circuit.

### BACKGROUND

### Technical Field

The present disclosure relates to a system of integrated circuits including a plurality of configuration bits and a protection bit. Each integrated circuit includes a programmable logic device including memory circuitry as configuration memory.

### Description of the Related Art

Programmable logic devices, such as field programmable gate arrays (FPGAs), are versatile integrated circuit chips, which have internal circuitry logic with user selected connections that a user can configure to realize user-specific functions. While programmable logic is versatile, there can be significant design challenges related to incorporating desired logic for a specified die size, routing signals, signal stability, etc. when large complex functions are mapped onto a silicon platform that includes programmable logic.

FPGAs are not typically immune to radiation. Radiation can be damaging to FPGAs and other integrated circuits where a charged particle can release a large number of electrons, which causes unpredictable behaviors, like noise and signal spikes. FPGAs used in radiation rich environments like outer space (especially beyond the low Earth orbit), around nuclear reactors and particle accelerators, or during nuclear accidents, benefit from radiation hardening to operate effectively.

Additionally, variations in power supply, temperature, or other environmental factors can cause the internal circuitry of an FPGA to malfunction. For FPGAs with many configuration bits, there is a risk that one configuration bit will malfunction, compromising the functionality of the entire FPGA, which is costly and wasteful. The ability to compensate for manufacturing defects or malfunctioning configuration bits would reduce the probability of producing a defective FPGA.

### BRIEF SUMMARY

The present disclosure is directed to a programmable logic device, such as field programmable gate arrays (FPGAs), that includes a plurality of individual magnetoresistive memory cells capable of consistent, reliable operation in radiation rich environments. The plurality of individual memory cells may include other types of memory cells, not just magnetoresistive random access memory cells. Conventionally, FPGAs include either distributed random access memory (RAM), which includes look up tables (LUTs) or block RAM, which does not include LUTs.

Distributed RAM may be more powerful than block RAM and outperform block RAM in terms of efficiency, while block RAM may have a higher capacity. However, both types of RAM cells in FPGAs have higher than standard failure rates.

The programmable logic device includes circuitry around a memory element that includes program circuitry and a latch. The circuitry includes a first logic gate coupled to a bit line and a second logic gate coupled to the first logic gate and the bit line. The first and second logic gates are configured to provide a “1” or “0” to the memory element in response to the bit line and a program signal. A third logic gate, such as an exclusive OR gate, is coupled to the latch. A multiplexer (MUX) is coupled to the third logic gate and the bit line. A tri-gate is coupled to the third logic gate, the MUX, and the bit line.

The circuitry allows the memory element to be programmed and the state of the memory element to be confirmed after programming. The circuitry is configured to support magnetic tunneling junction non-volatile memory elements, such as those that have been radiation hardened, i.e. configured to operate in radiation rich environments. The memory elements are configured to be configuration bits for the FPGA. Due to a higher than standard failure rate for such memory cells, the circuitry is configured to identify when the memory element does not receive the intended programmed state. The tri-gate allows the device to read back programmed data to confirm the latch includes the intended value. In addition, the circuitry allows for an option to address a memory element or cell that is stuck at a particular value or otherwise not working correctly.

There is a common bit line for a plurality of the memory elements where programming can occur at the same time. The structure of these memory elements and circuitry provide writing and loading multiple word lines simultaneously, while readback reading accesses only a single word line at a time.

A system of programmable logic devices includes a plurality of bit line shift registers each coupled to a respective bit line. The system includes a plurality of configuration bits and one protection bit, each coupled to a respective bit line. Each configuration bit includes a first plurality of logic components coupled to the respective bit line, a second plurality of logic components coupled to the first plurality of logic components and to the bit line, and a magnetoresistive memory circuit coupled between the first plurality of logic components and the second plurality of logic components. Each protection bit includes the first plurality of logic components coupled to the magnetoresistive memory circuit.

The system of programmable logic devices further includes a word line shift register, which is utilized when one of the configuration bits is malfunctioning. If one configuration bit malfunctions, the word line shift register delivers a signal to activate the protection bit. Including the protection bit in the system of programmable logic devices compensates for manufacturing defects and environmental factors that compromise the performance of a configuration bit.

### BRIEF DESCRIPTION OF THE SEVERAL VIEWS OF THE DRAWINGS

For a better understanding of the present disclosure, one or more embodiments will now be described by way of example only, with reference to the accompanying drawings. In the drawings, identical reference numbers identify similar elements or acts. In some figures, the structures are drawn exactly to scale. In other figures, the sizes of elements in the drawings are not necessarily drawn to scale. For example, the sizes, shapes of various elements and angles may be enlarged and positioned in the figures to improve drawing legibility.

FIG. 1 schematically is magnetoresistive memory circuitry for a configuration bit.

FIG. 2 is a plurality of signal inputs and outputs of magnetic tunnel junction circuitry in the memory circuitry of FIG. 1.

FIG. 3 schematically shows a plurality of individual magnetoresistive memory cells of the circuitry of FIG. 1.

FIG. 4 schematically shows a plurality of groups of the plurality of individual magnetoresistive memory cells of FIG. 3.

FIG. 5 schematically shows magnetoresistive memory circuitry for a protection bit.

FIG. 6 schematically shows a plurality of individual magnetoresistive memory cells of the circuits of FIG. 1.

FIG. 7 schematically shows a sub-array of the configuration bit circuitry of FIG. 1 and the protection bit of FIG. 5.

FIG. 8 schematically shows an embodiment of a memory element.

FIG. 9 schematically shows a plurality of individual memory elements of the circuitry of FIG. 8.

FIG. 10 is a diagram showing a first step of a process of using a redundancy bit to repair a manufacturing defect.

FIG. 11 is a diagram showing a second step of the process of using a redundancy bit to repair a manufacturing defect.

### DETAILED DESCRIPTION

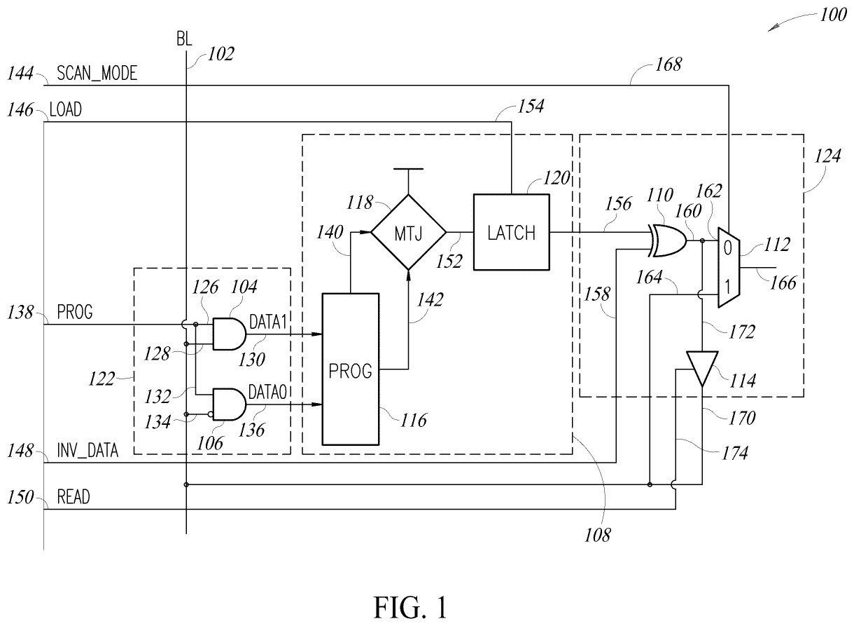

The present disclosure is directed to control circuitry 100 in a field programmable gate array (FPGAs) that includes magnetoresistive memory circuitry 108, such as magnetic random access memory (RAM), see FIG. 1. This circuitry 100 is configured to control, read, program, and test the accuracy of data in a memory element 118. This circuitry 100 is magnetoresistive memory circuitry for a configuration bit. This non-volatile memory element 118 is configured to operate in radiation rich environments, such as being radiation hardened for space applications. While the magnetoresistive random access memory is radiation-immune once it is fully programmed, the read and write circuitry may still be affected by radiation. Thus, the read and write circuitry must be radiation hardened. These memory elements 118 may be magnetic tunneling junction memory cells. These FPGAs are included in expanding technologies, like 5G and LPWAN connectivity, automotive, internet of things (IoT) due to the ability to reprogram FPGAs. Such FPGAs can be updated remotely or wirelessly, giving flexibility and the opportunity to update firmware.

FPGAs with a magnetoresistive random access memory (MRAM), such as memory elements 118 can simplify software associated with managing and programming the FPGA, i.e. updating new bitstreams into memory. MRAM memory elements have faster read and write capabilities with lower energy use. These radiation hardened memory elements have high reliability, with the surrounding circuitry including redundancy checks and a confirmation process that what is read matches what is stored in a respective memory element 118.

A group of these memory elements 118, each having their own circuitry 100, can be operated together as a plurality of configuration bit cells and a protection bit cell, such as X configuration bits and 1 protection bit. A plurality of these groups are in the FPGA. Memory elements 118 may be part of a configuration logic block, a digital signal processing (DSP) block, an input output (I/O) block, or another component of the FPGA. FIG. 1 is directed to a configuration bit or memory circuitry 108 that is surrounded by circuitry 100. Each memory circuitry includes a programming block 116, a memory cell 118, and a latch 120.

The memory element 118 can be magnetoresistive and non-volatile. According to some embodiments, the memory element 118 is a magnetic tunnel junction (MTJ). The memory element 118 may include two ferromagnets separated by a thin insulating layer, such that electrons may tunnel through the thin insulating layer between the two ferromagnets. The various layers of the MTJ are grown using a deposition method, for example molecular beam epitaxy, radio frequency sputtering, e-beam evaporation, or ion beam sputtering methods.

The memory element 118 is configured to be a low voltage device, where the low voltage cannot be used to drive logic connected to the memory element. The memory element 118 does retain the stored state across power ups and power downs, however when the element is an MTJ, the state is represented by a differential voltage between two resistors. The latch 120 is included and utilized to provide access to the state in the memory element 118. Every time the memory is powered up the state or data in the memory element 118 is moved to the latch. It is noted that the MTJ is powered down after a read to save power. This minimizes power leakage. The state is retained in the memory even when the device is powered off. This step, moving the memory element data to the latch, must be performed before the memory can be utilized.

The circuitry 100 around the memory circuitry 108 couples a bit line 102 to a first plurality of logic components 122. There are many memory cells coupled to this bit line 102. The first plurality of logic components 122 includes a first logic gate 104 coupled to the bit line 102 and a second logic gate 106 coupled to the bit line 102. The first plurality of logic components 122 are coupled to the memory circuitry 108 with DATA0 and DATA1 fed into programing circuitry 116.

The magnetoresistive memory circuitry 108 includes the programming circuitry 116, the memory element 118, and the latch 120. The memory element 118 is coupled to and between the programming circuitry 116 and the latch 120. A second plurality of logic components 124 are coupled to the latch 120 of the magnetoresistive memory circuitry 108.

The first plurality of logic components 122 are coupled to and control the programming circuitry 116. The first logic gate 104 includes a first input 126, a second input 128, and an output 130 (DATA1). The first input 126 of the first logic gate 104 is coupled to a programming line 138. The programming line 138 is configured to deliver a programming signal to the first logic gate 104. The first input 126 of the first logic gate 104 is also coupled to a first input 132 of the second logic gate 106. The second input 128 of the first logic gate 104 is coupled to the bit line 102.

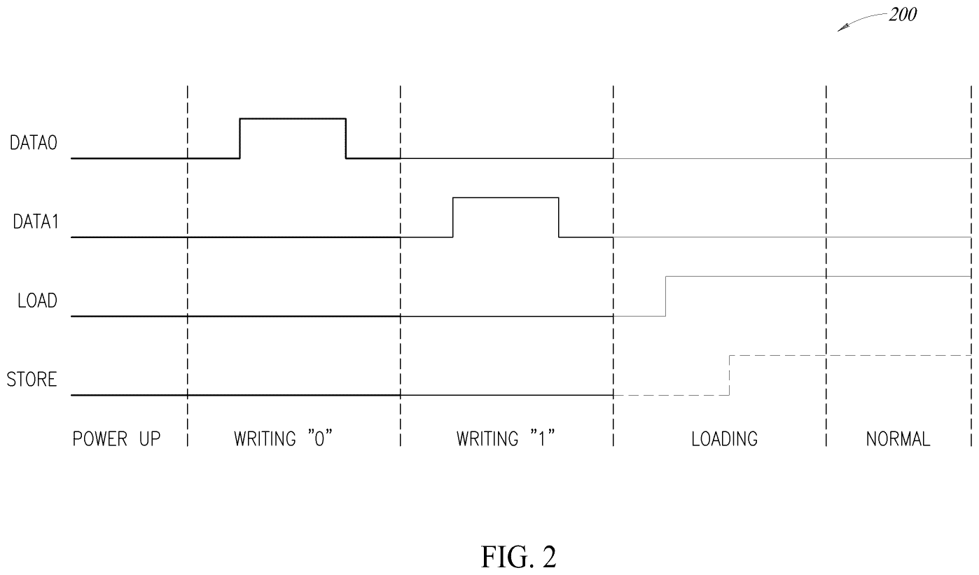

The second logic gate 106 includes the first input 132, a second input 134, and an output 136 (DATA0). The second input 134 of the second logic gate 106 is coupled to the bit line 102. According to some embodiments, the first logic gate 104 is an AND gate and the second logic gate 106 is an AND gate. In FIG. 1, the second input 134 of the second logic gate 106 is an inverted input. See FIG. 2 for further discussion of programming the memory element using the first plurality of logic components 122.

When working with MTJ cells, there is a probability that during a read, there will be a read error. This can be due to a variety of factors, including manufacturing defects. The circuitry 100 is configured to provide a mechanism to program and confirm what has been programmed in each memory element. If a bad cell is identified, the circuitry allows for an option to address or handle the bad cell without throwing away the device.

The output 130 of the first logic gate 104 and the output 136 of the second logic gate 106 may both be inputs to the programming circuitry 116. According to an embodiment, the programming circuitry 116 may be coupled to the memory element 118 with a first output 140 and a second output 142.

The memory element 118 may be coupled directly to a first input 152 of the latch 120. A second input 154 of the latch may be coupled to a load line 146. Other gate combinations are envisioned. The latch 120 is configured to receive a state or data stored in the memory element 118 in response to the load signal from the load line 146, which then is processed or otherwise received by the second plurality of logic components 124. The load signal loads data into the latch, which can be referred to as a data register. The load signal is representative of a read/write control signal for each memory cell. In some embodiments, it can be understood that the memory cell is in one mode or the other, i.e. if not in read mode, the cell is in write mode.

The second plurality of logic components 124 includes a third logic gate 110, a multiplexer (MUX) 112, and a tri-gate 114. The tri-gate 114 can be a tri state buffer. The third logic gate 110 includes a first input 156, a second input 158, and an output 160. The first input 156 of the third logic gate 110 is coupled directly to the latch 120. The second input 158 of the third logic gate 110 is coupled to an invert data line 148. The invert data line 148 is configured to deliver an invert data signal to the third logic gate 110. The invert data line 148 may couple together the second input 158 of the third logic gate 110 and a plurality of third logic gates 110 of each of the plurality of memory cells coupled along the bit line 102. According to some embodiments, the third logic gate 110 is an exclusive OR (XOR) logic gate. This XOR may operate as a buffer.

The MUX 112 is a 2×1 MUX and includes a first input 162, a second input 164, a first select input 168, and an output 166. The first input 162 of the MUX 112 is coupled directly to the output 160 of the third logic gate 110. The second input 164 of the MUX 112 is coupled to the bit line 102. The second input 164 of the MUX 112 is also coupled to an output 170 of the tri-gate 114. The first select input 168 of the MUX 112 is coupled to a scan mode line 144. The scan mode line 144 is configured to deliver a scan mode signal to the MUX 112. The scan mode signal is a global signal throughout the entire device. It is related only to the circuit's activation in the test mode, where the memory element operation is being isolated in normal application-specific integrated circuit (ASIC) testing methodology.

The tri-gate 114 includes an input 172, the output 170, and an enable terminal 174. The input 172 of the tri-gate 114 is coupled between the output 160 of the third logic gate 110 and the first input 162 of the MUX 112. The output 170 of the tri-gate 114 is coupled to the second input 164 of the MUX 112 and to the bit line 102. The enable terminal 174 of the tri-gate 114 is coupled to a read line 150. The read line 150 is configured to deliver a read signal to the tri-gate 114.

Once the load signal delivers data into the latch 120, the tri-gate 114 is included to allow for the option of reading back the data in the memory element 118 and the latch 120. This provides circuitry to compensate for the higher failure rate of MTJ memory cells. Said differently, the tri-gate provides an opportunity to read the configuration bit data back to the bit line so that that it can be stored and compared to what was programmed. For example, during a programming mode, the system can first drive a “1” or a “0” on the bit line to program the memory element 118, with the programming line 138 being activated. Then, the bit line is tristated and the system is configured to read back what is on the latch through the tri-gate. This arrangement allows writing a cell and reading it back.

The tri-gate 114 is coupled to the input of the MUX. In a normal mode, such as normal operation of the FPGA, the data in the configuration bits are used to configure or program the FPGA. The output of the MUX will be coupled to other MUXs and circuitry (not shown) that determine how to route the FPGA.

The circuitry 100 is configured to provide for a testing option, before the FPGA is provided to an end customer. During manufacturing, the configuration bit can be tested to identify any bad cells or defects in the memory. To perform such testing, the MUX is included. In addition, the shared programming bit line register allows for this design for test ability. FIG. 2 is a graph or representation 200 of the plurality of signal inputs and outputs of the circuitry 100 of FIG. 1 utilized to program and utilize the memory element 118. The graph 200 includes the first signal DATA0 and the second signal DATA1 that are received by the programming circuitry 116. In order to write a zero “0” to the MTJ, DATA0 goes high or is otherwise activated based on the signals received on the programming line 138 and the bit line 102. DATA0 is high and DATA1 is low. The LOAD signal 154 subsequently goes high after DATA0 goes high, which triggers loading or storing of zero “0.” Conversely, when DATA1 is high and DATA0 is low, the LOAD signal 154 subsequently goes high, storing the one “1” value in the memory element. It is noted that STORE is an internal signal within the memory element 108. This STORE signal may be shared across the X related bits of a plurality of individual magnetoresistive memory cells.

When the FPGA is powered up and DATA0 and DATA1 are not asserted, but LOAD is high, the non-volatile contents of the memory cell 118 are moved into the latch 120. The signals are stabilized and considered in a normal mode NORMAL after the storing or programming has occurred. In the normal mode NORMAL, the data in the memory cell is now ready to be read by the circuitry 100 of FIG. 1 and utilized by the FPGA for configuration or general use.

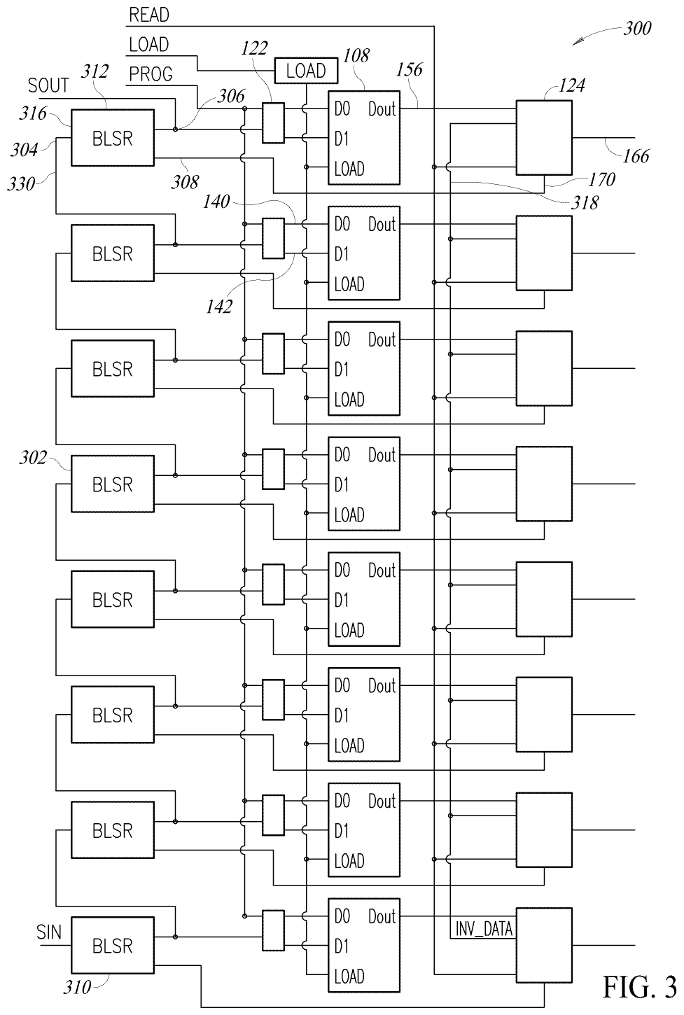

FIG. 3 is a first system 300 including a plurality of circuits 100 of FIG. 1. More specifically, the first system 300 includes a plurality of Bit Line Shift Registers (BLSRs) 302, each of which is coupled to a respective one of the first plurality of logic components 122, a magnetoresistive memory circuitry 108, and a second plurality of logic components 124. In this embodiment, there are 8 memory bits, 8 BLSRs, etc. In one embodiment, 7 of the memory cells will be configuration bits and 1 will be a protection bit. There is a shared LOAD block that is coupled to the LOAD signal, which moves the data from the memory element to the latch. This LOAD can be used in read and write modes. The plurality of BLSRs 302 are coupled in sequence, each with a unique bit line 102. That is, each BLSR 302 includes a first input 304 and a first output 306 coupled to the bit line 102. The first output 306 of each BLSR 302 is coupled to a first input 304 of another one of the plurality of BLSRs 302. Each BLSR 302 includes a second input 308 that is directly coupled to the output 170 of the second plurality of logic components 124, which is the output of the tri-gate 114. According to other embodiments, the output 170 of the second plurality of logic components 124 may be coupled to a BLSR 302 that is different from the respective BLSR 302 of the second plurality of logic components 124.

The plurality of BLSRs 302 includes a first BLSR 310. Instead of being coupled to the first output 306 of another one of the plurality of BLSRs 302, the first input 304 of the first BLSR 310 is coupled to an input signal line SIN. The input signal line SIN is configured to deliver an input signal to the first BLSR 310.

The plurality of BLSRs 302 includes a last BLSR 316. Instead of being coupled to the first input 304 of another one of the plurality of BLSRs 302, the first output 306 of the last BLSR 316 is coupled to an output signal line SOUT. The output signal line SOUT is configured to deliver an output signal from the last BLSR 316. Although eight BLSRs 302 are shown in FIG. 3, embodiments may include more or fewer BLSRs 302.

The BLSRs are how the bit line is coupled to the memory cells. In order to shift an 8 bit pattern into the plurality of individual of memory cells, the pattern is provided to SIN in the first BLSR 310 and shifted or snaked into each BLSR. As SIN is activated and shifts into each BLSR, the program signal is turned on and what is in the respective BLSR is moved into the programming circuity 122 and into the memory cell 118. The programming circuitry will drive the logic to write a “1”or “0,”i.e. the value in the related BLSR into the memory element 108.

The first output 306 of each of the plurality of BLSRs 302 is further coupled to the first plurality of logic components 122. The first plurality of logic components 122 may include the first logic gate 104 coupled to the bit line 102 and the second logic gate 106 coupled to the bit line 102 and to the first logic gate 104. These components are shown in FIG. 1.

Additionally, the programming line PROG is coupled to the first plurality of logic components 122. More specifically, the programming line PROG may be coupled to the first logic gate. The programming line PROG is configured to deliver a programming signal to the first plurality of logic components 122. The first plurality of logic components 122 includes a first output 136 and a second output 130, both of which are inputs to the magnetoresistive memory circuitry 108.

Although eight first pluralities of logic components 122 are shown in FIG. 3, embodiments may include more or fewer first pluralities of logic components 122. Each BLSR 302 is coupled to a first plurality of logic components 122. Thus, there will be an equal number of BLSRs 302 and first pluralities of logic components 122 and memory elements. The magnetoresistive memory circuitry 108 will include the programming circuit, the memory element, and the latch. These components are shown in FIG. 1.

The magnetoresistive memory circuitry 108 includes a first input D0 that is coupled to the first output 136 of the first plurality of logic components 122. The magnetoresistive memory circuitry 108 includes a second input D1 that is coupled to the second output 130 of the first plurality of logic components 122. The first input D0 and the second input D1 may be coupled directly to the programming circuitry of the magnetoresistive memory circuitry 108.

The magnetoresistive memory circuitry 108 includes a third input LOAD that is coupled to the LOAD line and shared LOAD circuitry. The third input LOAD may be coupled directly to the latch of the magnetoresistive memory circuitry 108.

The magnetoresistive memory circuitry 108 includes a first output Dout, which may be coupled directly between the latch of the magnetoresistive memory circuitry 108 and the second plurality of logic components 124.

Although eight magnetoresistive memory circuitries 108 are shown in FIG. 3, embodiments may include more or fewer magnetoresistive memory circuitries 108. Each first plurality of logic components 122 is coupled to a magnetoresistive memory circuitry 108. Thus, there will be an equal number of BLSRs 302, first pluralities of logic components 122, and magnetoresistive memory circuitries 108.

The second plurality of logic components 124 may include a third logic gate, a MUX, and a tri-gate. These components are shown in FIG. 1.

The second plurality of logic components 124 includes a first input 156 which is directly coupled to the first output Dout of the magnetoresistive memory circuitry 108. The first input 156 of the second plurality of logic components 124 may be directly coupled to the third logic gate 110. The second plurality of logic components 124 includes a second input 318 coupled to an invert data line. The invert data line couples together each second plurality of logic components 124. The protection bit serves as an indicator to provide the invert data lines.

A scan mode line is not illustrated in FIG. 3 for simplicity, but the scan mode signal is a global signal throughout the entire device.

The second plurality of logic components 124 includes a first output 166 and a second output 170. The first output 166 of the second plurality of logic components 124 is the output of the MUX and is coupled to the FPGA circuitry. The second output 170, from the tri-gate, of the second plurality of logic components 124 is coupled to the respective BLSR 302 of the plurality of BLSRs 302 for reading and evaluating if the data in the memory cell is what was programmed. More specifically, the second output 170 of the second plurality of logic components 124 is coupled to the second input 308 of the respective BLSR 302 of the plurality of BLSRs 302. The second output 170 of the second plurality of logic components 124 may be coupled to the output of the tri-gate.

Each magnetoresistive memory circuitry 108 is coupled to a second plurality of logic components 124. Thus, there will be an equal number of BLSRs 302, first pluralities of logic components 122, magnetoresistive memory circuitries 108, and second pluralities of logic components 124.

A word line shift register (not shown) is provided to control the read, programming, and load signals. A total of eight BLSRs 302 may be included for each word line driver. A read mode is utilized for booting the plurality of individual memory cells. A program mode is for writing or programming the memory elements. LOAD is used to reload the data from the memory element into the shift register to confirm the accuracy of the data.

In this arrangement, there are X bit line drivers for one word line driver. In FIG. 3, X is 8. The tri-state driver allows for X bits per X groups. With multiple groups being enabled simultaneously.

Each BLSR 302 and its corresponding first plurality of logic components 122, magnetoresistive memory circuitry 108, and second plurality of logic components 124 comprises a bit group. The tri-gate, shown in FIG. 1, allows all eight bit groups to be enabled simultaneously for verification of correct programming.

The LOAD block, which represents READ in some modes, is a common programming block across X MTJs and latches, memory elements 108. While the read and write control signals are common to all X MTJs, write data is separate for each MTJ cell. Load and read operations can be done to all MTJs simultaneously, while write data must be written one row of memory cells at a time.

It is noted that, when the LOAD signal is activated, it will trigger the internal STORE signal. Once activated, STORE allows the latch to capture data in the MTJ with a delay after read or LOAD goes high.

The exclusive OR, XOR gate 110 is incorporated to address when the latch does not include the data that was intended to be programmed, such as manufacture defects in the memory elements. This is in response to a tri-gate returning, during the read back or check, a value in the latch that is not what was intended to be programmed. An extra memory cell or MTJ will be included to provide for data inversion with the XOR gate to address the defect. There may, for example, be one repair bit for every seven regular bits or one repair bit for every fifteen regular bits. There may be more or fewer repair bits for each regular bit. The repair bit may be outside of a bit group. In short, the circuitry allows the whole row to be “fixed” or programmed to be all either a “1” or a “0”. More specifically, one repair bit can repair one manufacturing defect. The repair bit can only repair one damaged bit.

In a full system, a group of these memory elements 118, each having their own circuitry 100, can be operated together as a plurality of configuration bit cells and a protection bit cell, such as X-1 configuration bits and 1 protection (repair) bit. A plurality of these groups are in the FPGA, and the FPGA includes a plurality of configuration logic blocks (CLBs). The plurality of these groups may be included in one of the plurality of CLBs, in a block random access memory (bRAM) block, an input output (I/O) random access memory block, or another block in the FPGA. In each FPGA, there are X word lines, for which each word line can be coupled to a number of the groups. Each first word line of each FPGA can be activated simultaneously. The tri-gates are included in all X of the configuration bits. This allows for the readback of the intended programmed value and for the opportunity to address any identified bad cell.

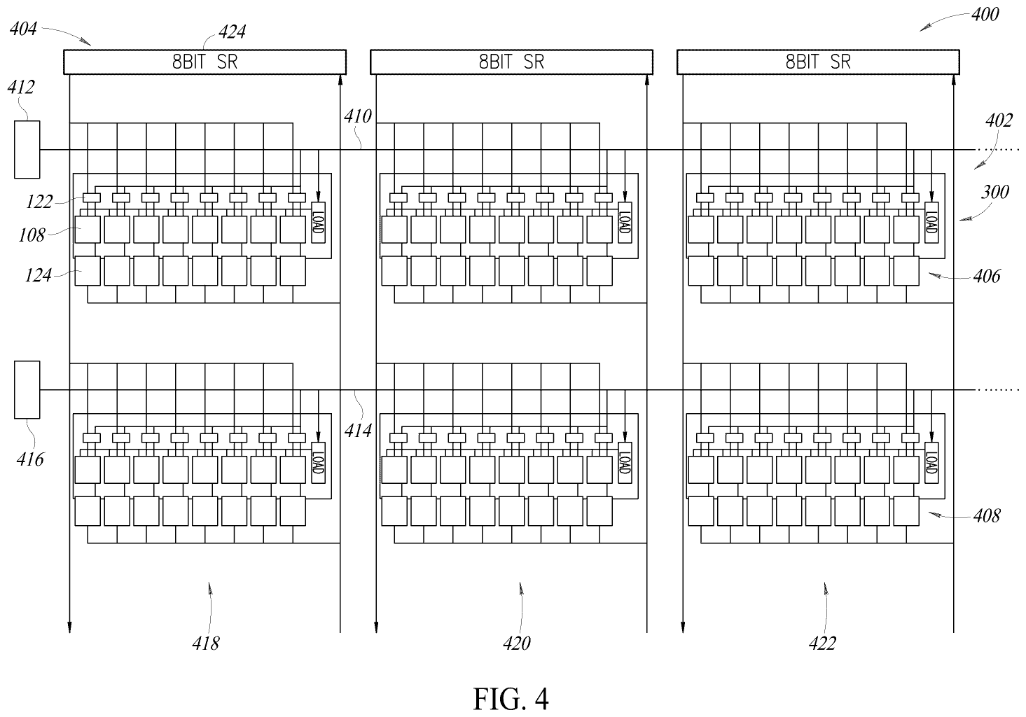

FIG. 4 is a plurality of groups of plurality of individual magnetoresistive memory cells 400 including a plurality of first sub-systems 300 of FIG. 3 arranged along a plurality of rows 402 and columns 404. Although two rows 402 and three columns 404 are depicted in FIG. 4, embodiments will include more rows 402 or columns 404. The two rows 402 depicted in FIG. 4 include a first row 406 and a second row 408. The three columns 404 depicted in FIG. 4 include a first column 418, a second column 420, and a third column 422. Each first system 300 of the plurality of first systems 300 includes a plurality of magnetoresistive memory circuits 108. Each magnetoresistive memory circuit 108 is coupled between a first plurality of logic components 122 and a second plurality of logic components 124.

Each first system 300 along the first row 406 is coupled to a first word line 410. More specifically, the first word line 410 is coupled directly to each first plurality of logic components 122 of each first system 300 of the plurality of first systems 300 in the first row 406. Each first word line 410 is coupled to a first word line shift register (WLSR) 412. Each first system 300 along the second row 408 is coupled to a second word line 414. More specifically, the second word line 414 is coupled directly to each first plurality of logic components 122 of each first system 300 of the plurality of first systems 300 in the second row 408. Each second word line 414 is coupled to a second WLSR 416.

The first WLSR 412 and second WLSR 416 are configured to transmit the read signal, programming signal, and load signal.

The first column 418 of first systems 300 includes a first eight-bit shift register 424 coupled to a plurality of outputs 166 of each of the second pluralities of logic components 124 of the first systems 300 along the first column 418. The first eight-bit shift register 424 is coupled to each first plurality of logic components 122 of each first system 300 of the plurality of first systems 300 in the first column 418. While the shift register is noted to be 8-bit, this is representative and other X-bit arrangements are intended.

The configuration of eight-bit shift registers 424 allows independent programming and load operations, which optimizes the number of MTJ programming and load signals per programming cycle. This reduces the power consumption of the memory plurality of groups of plurality of individual magnetoresistive memory cells 400.

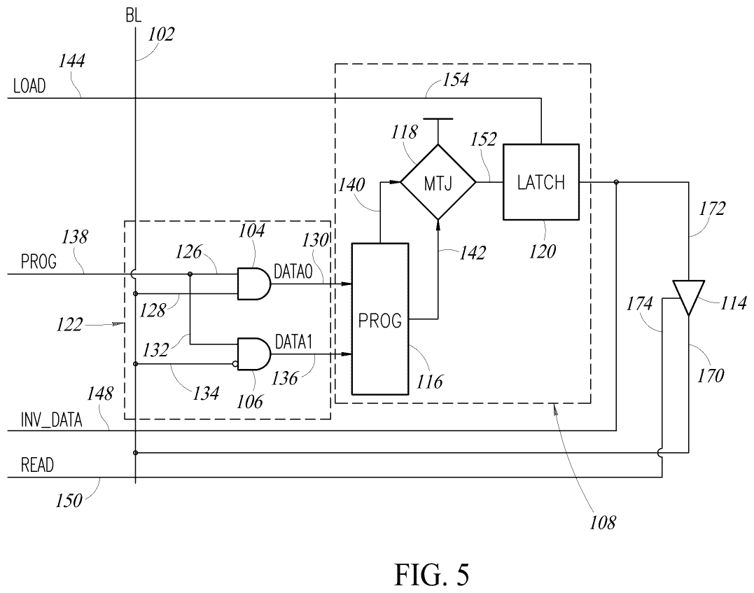

FIG. 5 is a protection bit 501 including memory circuitry 108 and a bit line 102 coupled to a first plurality of logic components 122. The protection bit 501 is differentiated from the circuitry 100 of the configuration bit described in FIG. 1 because the protection bit 501 does not include a third logic gate 110 or a MUX 112. Instead, the memory circuitry 108 is coupled directly to a tri-gate 114.

The first plurality of logic components 122 includes a first logic gate 104 coupled to the bit line 102 and a second logic gate 106 coupled to the bit line 102 and to the first logic gate 104. The first plurality of logic components 122 are coupled to the memory circuitry 108 with DATA0 and DATA1 fed into programing circuitry 116.

The magnetoresistive memory circuitry 108 includes the programming circuitry 116, the memory element 118, and a latch 120. The memory element 118 is coupled to and between the programming circuitry 116 and the latch 120. A tri-gate 114 is coupled to the latch 120 of the magnetoresistive memory circuitry 108.

The first plurality of logic components 122 are coupled to and control the programming circuitry 116. The first logic gate 104 includes a first input 126, a second input 128, and an output 130 (DATA1). The first input 126 of the first logic gate 104 is coupled to a programming line 138. The programming line 138 is configured to deliver a programming signal to the first logic gate 104. The first input 126 of the first logic gate 104 is also coupled to a first input 132 of the second logic gate 106. The second input 128 of the first logic gate 104 is coupled to the bit line 102.

The second logic gate 106 includes the first input 132, a second input 134, and an output 136 (DATA0). The second input 134 of the second logic gate 106 is coupled to the bit line 102. According to some embodiments, the first logic gate 104 is an AND gate and the second logic gate 106 is an AND gate. In FIG. 5, the second input 134 of the second logic gate 106 is an inverted input.

The output 130 of the first logic gate 104 and the output 136 of the second logic gate 106 are both inputs to the programming circuitry 116. The programming circuitry 116 is coupled to the memory element 118 with a first output 140 and a second output 142.

As in the circuitry 100 of FIG. 1, the memory element 118 in FIG. 5 can be magnetoresistive and non-volatile. According to some embodiments, the memory element 118 is a magnetic tunnel junction (MTJ). The memory element 118 may include two ferromagnets separated by a thin insulating layer, such that electrons may tunnel through the thin insulating layer between the two ferromagnets. The various layers of the MTJ are grown using a deposition method, for example molecular beam epitaxy, radio frequency sputtering, e-beam evaporation, or ion beam sputtering methods.

The memory element 118 is coupled directly to a first input 152 of the latch 120. A second input 154 of the latch is coupled to a load line 146. The latch 120 is configured to receive a state or data stored in the memory element 118 in response to the load signal from the load line 146, which then is processed or otherwise received by the tri-gate 114. The load signal loads data into the latch, which can be referred to as a data register. The load signal is representative of a read/write control signal for each memory cell. In some embodiments, it can be understood that the memory cell is in one mode or the other, i.e. if not in read mode, the cell is in write mode.

The tri-gate 114 includes an input 172, an output 170, and an enable terminal 174. The tri-gate can be a tri-state buffer. The input 172 of the tri-gate is directly coupled to the latch 120. The output of the tri-gate 114 is coupled to the bit line 102. The enable terminal 174 of the tri-gate 114 is coupled to a read line 150. The read line 150 is configured to deliver a read signal to the tri-gate 114.

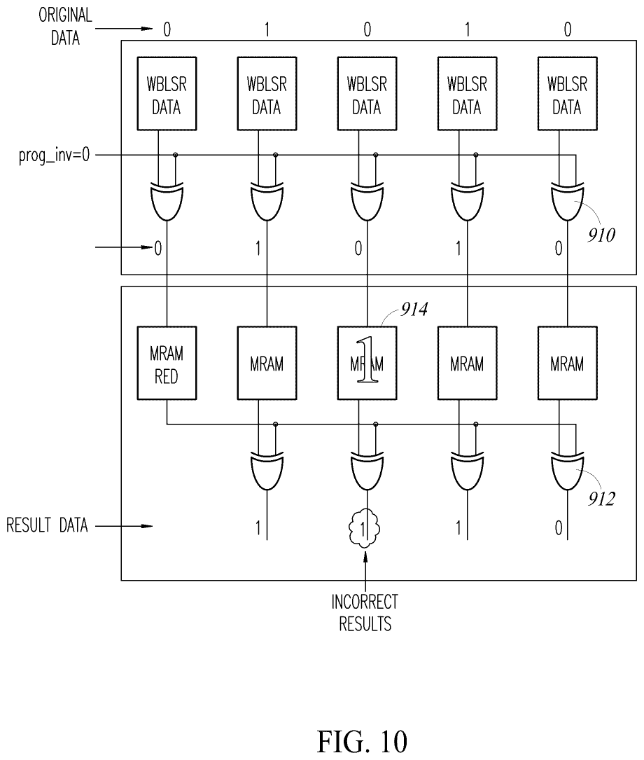

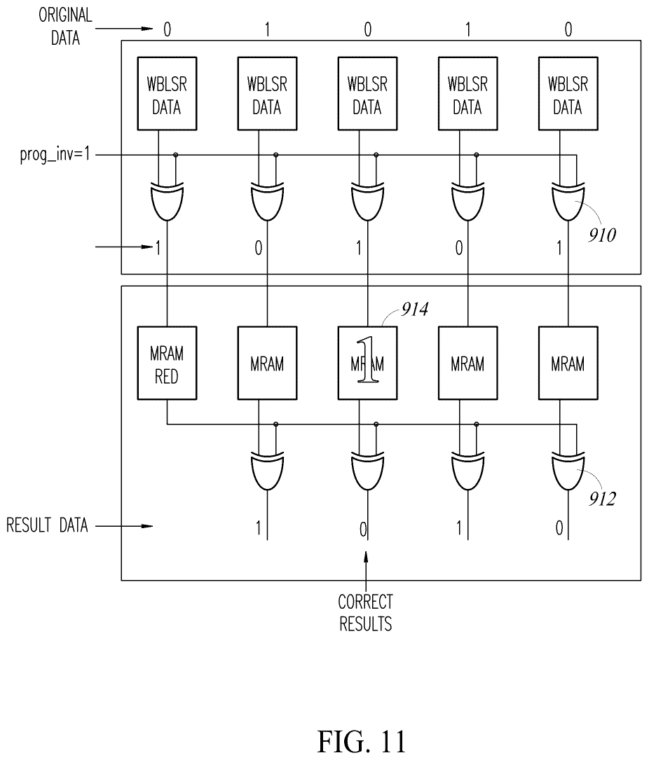

One protection bit 501 may be coupled with a plurality of configuration bits such that, if the memory element 118 in a configuration bit is defective and unable to hold a data value, the defect will be detected during a read stage and the protection bit 501 will be activated. There may be one protection bit 501 coupled with a plurality of seven configuration bits. See FIGS. 10 and 11 for a description of the function of a protection bit among a plurality of configuration bits.

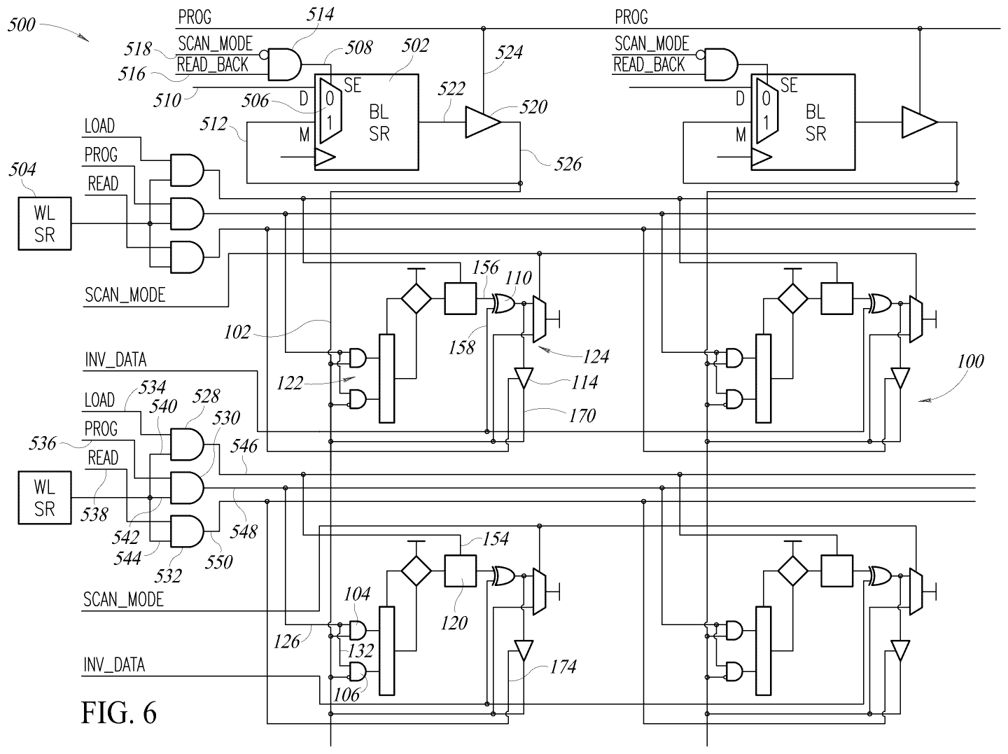

FIG. 6 is a second system 500 including a plurality of circuits 100 of FIG. 1.

More specifically, the second system 500 includes a plurality of BLSRs 502 each coupled to a bit line 102 of the plurality of circuits 100 of FIG. 1. Additionally, the second system 500 includes a plurality of WLSRs 504 coupled to a plurality of AND gates that receive the read line READ, the programming line PROG, and the load line LOAD.

Each BLSR 502 includes a second MUX 506 with a first input 510 and a second input 512, where the second input 512 is coupled to an output of the BLSR 502. Each second MUX 506 further includes a first select input 508 which is directly coupled to an output of a third logic gate 514. The third logic gate 514 may be an AND gate. The third logic gate 514 has a first input 518 that is an inverted input and is coupled directly to the scan mode line SCAN_MODE. The scan mode line SCAN_MODE is configured to deliver a scan mode signal to the third logic gate 514. The scan mode signal is a global signal throughout the entire device. The third logic gate 514 has a second input 516 that is directly coupled to a read back line READ_BACK, which is configured to deliver a read back signal to the third logic gate 514.

A first output 522 of the BLSR 502 is a first input of a second tri-gate 520. The tri-gate 520 has an enable terminal 524 that is directly coupled to the programming line PROG. The tri-gate 520 has an output 526 that is directly coupled to the second input 512 of the second MUX 506 of the BLSR 502. The output 526 of the tri-gate 520 is also coupled to the bit line 102. That is, the bit line 102 is coupled to both the output 526 of the tri-gate 520 and to the second input 512 of the second MUX 506 that is in the BLSR 502. The bit line 102 is bi-directional.

The bit line 102 is driven by at least two sources, the bit line driver and the feedback from tri-gate 114 of circuit 100. To avoid bus contention, each tri-gate 114 of each circuit 100 is enabled one at a time through a gate control signal. During write operations, the output 526 of the tri-gate 520 drives the data toward the circuit 100. During read operations, the circuit 100 is driving the bit line 102 toward the bit line driver so the read data can be captured in the BLSR 502 to be shifted out for observation.

The bit line 102 extends through multiple circuits 100. Although only four circuits 100 are shown in FIG. 6, this number may be greater than four in a final design. Each bit line 102 is coupled directly to each first plurality of logic components 122 of each circuit 100. Additionally, the output of each second plurality of logic components 124 of each circuit 100 is coupled directly to the bit line 102. More specifically, the output 170 of each tri-gate 114 is coupled directly to the bit line 102. See FIG. 1 for more details.

Each WLSR 504 controls the read, programming, and load signals. More specifically, the load signal is transmitted along the load line LOAD, which is coupled directly to a first input 534 of a read logic component 528. The load logic component 528 may be an AND gate. The programming signal is transmitted along the programming line PROG, which is coupled directly to a first input 536 of a programming logic component 530. The programming logic component 530 may be an AND gate. The read signal is transmitted along the read line READ, which is coupled directly to a first input 538 of a load logic component 532. The read logic component 532 may be an AND gate. The load logic component 528 has a second input 540 which is coupled directly to a second input 542 of the programming logic component 530 and to a second input 544 of the read logic component 532. The WLSR 504 is coupled directly to the second input 540 of the load logic component 528, the second input 542 of the programming logic component 530, and to the second input 544 of the read logic component 532.

An output 546 of the load logic component 528 is coupled directly to a second input 154 of a latch 120 of each circuit 100. An output 548 of the programming logic component 530 is coupled directly to the first plurality of logic components 122 of each circuit 100. More specifically, the output 548 of the programming logic component 530 is coupled directly to a first input 126 of a first logic device 104 of the first plurality of logic components 122 and a first input 132 of a second logic device 106 of the first plurality of logic components 122. An output 550 of the read logic component 532 is coupled directly to the second plurality of logic components 124 of each circuit 100. More specifically, the output 550 of the read logic component 532 is coupled directly to an enable terminal 174 of each tri-gate 114 of the second plurality of logic components 124. The description for FIG. 1 includes more details for the specific coupling within each circuit 100.

Each circuit 100 includes a logic gate 110 with a first input 156 coupled to the latch 120 and a second input 158. Each of the second inputs 158 of each logic gate 110 in each circuit 100 are coupled together. An invert data INV_DATA line is coupled to each second input 158 of each logic gate 110. In a cluster of bits, where one bit is a protection (repair) bit, the protection bit serves as an indicator to provide the invert data INV_DATA lines.

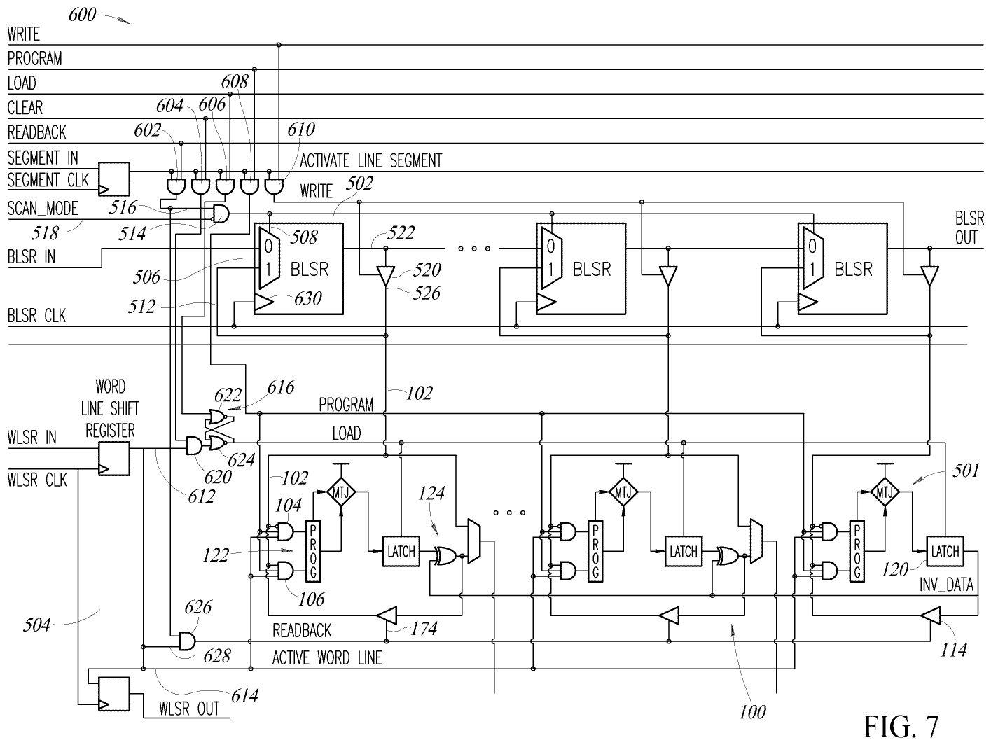

FIG. 7 is a second system 600 including a plurality of circuits 100 of FIG. 1 and a protection bit 501 of FIG. 5. More specifically, the system 600 includes a plurality of BLSRs 502 each coupled to a bit line 102 of the plurality of circuits 100 of FIG. 1 or the protection bit 501 of FIG. 5. The system 600 further includes a WLSR 504 coupled to a read line READ, a programming line PROG, and a load line LOAD.

Each BLSR 502 includes a MUX 506 with a first input BLSR IN and a second input 512, the second input 512 being coupled to an output of each of the plurality of BLSRs 502. Each MUX 506 further includes a select input 508 directly coupled to a logic gate 514 and to each select input 508 of each of the plurality of BLSRs 502. The logic gate 514 may be an AND gate. The logic gate 514 has a first input 518 that is an inverted input and is coupled directly to the scan mode line SCAN_MODE. The scan mode line SCAN_MODE is configured to deliver a scan mode signal to the logic gate 514 to the logic gate 514. The logic gate 514 has a second input 516 that is coupled to a read back line READBACK.

Each BLSR 502 receives a BLSR clock signal delivered along a BLSR clock line BLSR CLK. An output 522 of the BLSR 502 is coupled to a tri-gate 520.

A plurality of Segment In logic components 602, 604, 606, 608, 610 each have a first input coupled to a Segment In line SEGMENT IN. The first Segment In logic component 602 has a second input coupled to the read back line READBACK and an output coupled to the second input 516 of the logic gate 514. The read back line READBACK is configured to deliver a read back signal to each BLSR 502.

A first output 522 of each BLSR 502 is a first input of a tri-gate 520, the tri-gate 520 having an output 526 that is directly coupled to the second input 512 of the MUX 506 in each BLSR 502. The output 526 of the tri-gate 520 is also coupled to the bit line 102 in each respective configuration bit 100 or protection bit 501. That is, the bit line 102 is coupled to both the output 526 of the tri-gate 520 and to the second input 512 of the MUX 506 in the BLSR 502. The bit line 102 is bi-directional.

Each bit line 102 may extend through multiple configuration bits 100 or protection bits 501. Each bit line 102 is coupled directly to each first plurality of logic components 122 of each configuration bit 100 or protection bit 501. Additionally, the output of each second plurality of logic components 124 of each configuration bit 100 and the output of the tri-gate 114 in the protection bit 501 is coupled to each bit line 102. The description for FIG. 1 and FIG. 5 include details of the specific couplings of each circuit 100 and each protection bit 501.

The WLSR 504 controls the readback, programming, and clear signals. While multiple word lines are loaded simultaneously, only a single line can be read or programmed at one time. The program requires that a word line be cleared with the clear signal first, followed by a program signal. More specifically, the load signal is transmitted along the load line LOAD, which is coupled to a third Segment In logic component 606 of the plurality of Segment In logic components. The output of the third Segment In logic component 606 is coupled to a third plurality of logic components 616, which may include a plurality of AND gates and a plurality of NOR gates. The load line LOAD continues through the third plurality of logic components 616 and is coupled to each latch 120 of each configuration bit 100 and each protection bit 501.

The third plurality of logic components 616 may include a first logic gate 620, which may be an AND gate and has an input coupled to a first output 612 the WLSR 504 and an input coupled to a second Segment In logic component 604 of the plurality of Segment In logic components. The second Segment In logic component 605 is coupled to a clear line CLEAR that is configured to deliver a clear signal to each configuration bit 100 and each protection bit 501. The load line LOAD is an input to a second logic gate 622, which may be an NOR gate. The output of the second logic gate 622 of the third plurality of logic components 616 is an input to a third logic gate 624. A second input of the third logic gate 624 is an output of the first logic gate 620. The output of the third logic gate 624 is an input of the second logic gate 622 and is coupled to the load line LOAD.

The programming signal is transmitted along the programming line PROGRAM, which is coupled to a fourth Segment In logic component 608 of the plurality of Segment In logic components. The output of the fourth Segment In logic component 608 is coupled to each first logic gate 104 and second logic gate 106 of each first plurality of logic components 122 of each configuration bit 100 and each protection bit 501.

The readback signal is transmitted along the readback line READBACK, which is coupled to the first Segment In logic component 602. The readback line READBACK is an input to a readback logic gate 626 which may be an AND gate. A second input of the readback logic gate 626 is a second output 628 of the WLSR 504. An output of the readback logic gate 626 is coupled to an enable terminal 174 of each tri-gate 114 in each configuration bit 100 and each protection bit 501.

A third output 614 of the WLSR 504 is coupled to an active word line ACTIVE WORD LINE, which is a third input of each first logic gate 104 and each second logic gate 106 of each first plurality of logic components 122.

In FIG. 6, each first logic gate 104 and each second logic gate 106 have two inputs, the common programming signal PROG 536 being implied to be prequalified with the WLSR 504 is shown in FIG. 6. The 2-input AND gate, programming logic component 530, is combined with each first logic gate 104 and each second logic gate 106, creating three inputs for each AND gate, the first logic gate 104 and the second logic gate 106 in FIG. 7.

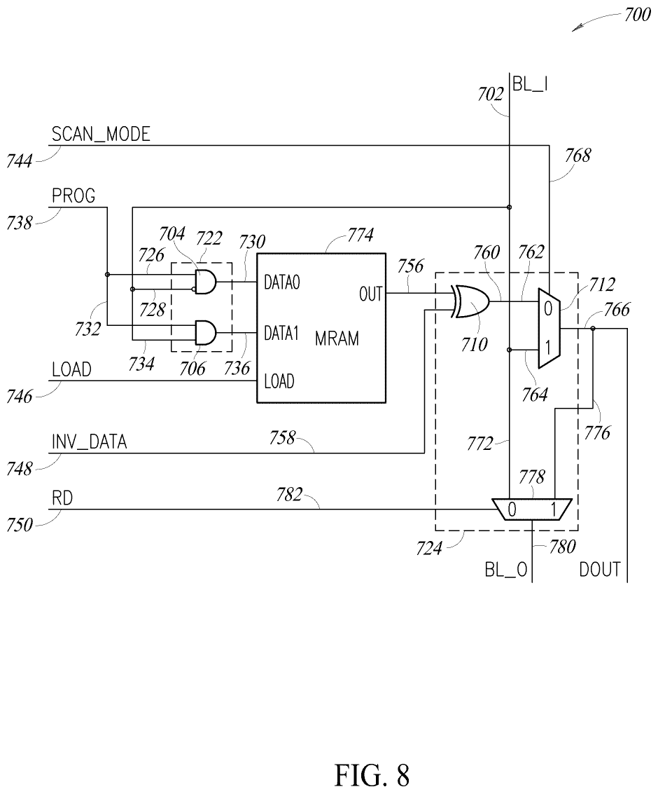

FIG. 8 shows another embodiment of a memory element of the present disclosure. Circuitry 700 includes a bit line 702 coupled to a first plurality of logic components 722. The bit line 702 is only connected to a single memory cell. The first plurality of logic components 722 includes a first logic gate 704 and a second logic gate 706, both coupled to the bit line 702. The first plurality of logic components 722 are coupled to the memory element 774 with DATA0 and DATA1 fed into the memory element 774.

The first logic gate 704 includes a first input 726 coupled to a programming line 738. The programming line 738 is configured to deliver a programming signal to the first logic gate 704. The first input 726 of the first logic gate 704 is also coupled to a first input 732 of the second logic gate 706. A second input 728 of the first logic gate 704 is coupled to the bit line 702. The second input 728 of the first logic gate 704 is an inverted input. An output 730 of the first logic gate 704 is coupled to a first input DATA0 of the memory element 774.

The second logic gate 706 has a second input 734 coupled to the bit line 702 and an output 736 coupled to a second input DATA1 of the memory element 774. According to some embodiments, the first logic gate 704 is an AND gate and the second logic gate 706 is an AND gate.

A second plurality of logic components 724 is coupled to an output OUT of the memory element 774. The second plurality of logic components 724 includes a third logic gate 710, a first MUX 712, and a second MUX 778. A first input 756 of the third logic gate 710 is coupled to the output OUT of the memory element 774 and a second input 758 of the third logic gate 710 is coupled to an invert data line 748. The invert data line 748 is configured to deliver an invert data signal to the third logic gate 710. The invert data line 748 may couple together the second input 758 of the third logic gate 710 and a plurality of third logic gates 710 of each of the plurality of memory cells. One of the plurality of memory cells coupled along the bit line 702 is a protection bit. The protection bit serves as an indicator to provide the invert data lines 748. According to some embodiments, the third logic gate 710 is an XOR logic gate. This XOR may operate as a buffer.

The first MUX 712 is a 2×1 MUX and includes a first input 762 coupled directly to an output 760 of the third logic gate 710. A second input 764 of the first MUX 712 is coupled to the bit line 702 and to a first input 772 of the second MUX 778. A first select input 768 of the first MUX 712 is coupled to a scan mode line 744. The scan mode line 744 is configured to deliver a scan mode signal to the first MUX 712. The scan mode signal is a global signal throughout the entire device. It is related only to the circuit's activation in the test mode, where the memory element operation is being isolated in normal application-specific integrated circuit (ASIC) testing methodology.

The second MUX 778 is a 2×1 MUX and includes a second input 776 coupled to an output 766 of the first MUX 712. A first select input 782 of the second MUX 778 is coupled to a read line 750 that is configured to deliver a read signal to the second MUX 778. The second MUX 778 isolates the bit line 702 from an output 780 of the second MUX 778. The output 780 of the second MUX 778 is a bit line output BL_0, which is coupled to a subsequent memory cell in a chain of memory cells. A structure including the bit line 702, the second MUX 778, and the bit line output BL_0 is repeated in each subsequent memory cell in the chain of memory cells. This repeated structure creates the bit line 102 of FIG. 1.

The second MUX 778 of FIG. 8 replaces the tri-gate 114 of FIG. 1. Because of this change, the bit line 702 is no longer bi-directional. Additionally, when multiple configuration bits are concatenated, each configuration bit requires an independent read signal and only one read signal can be activated at once. During the write mode, the second MUX 778 will select the bit line 702 output BL_O, allowing the bit line 702 output BL_O to drive the configuration data. Once the programming signal is activated, the data will be written in the memory element.

During read back mode, only one read signal of one of the configuration bits will be activated. For the activated configuration bit, the second MUX 778 will select an output of the configuration bit DOUT as an input and the read data will propagate through each second MUX 778 of each concatenated configuration bit.

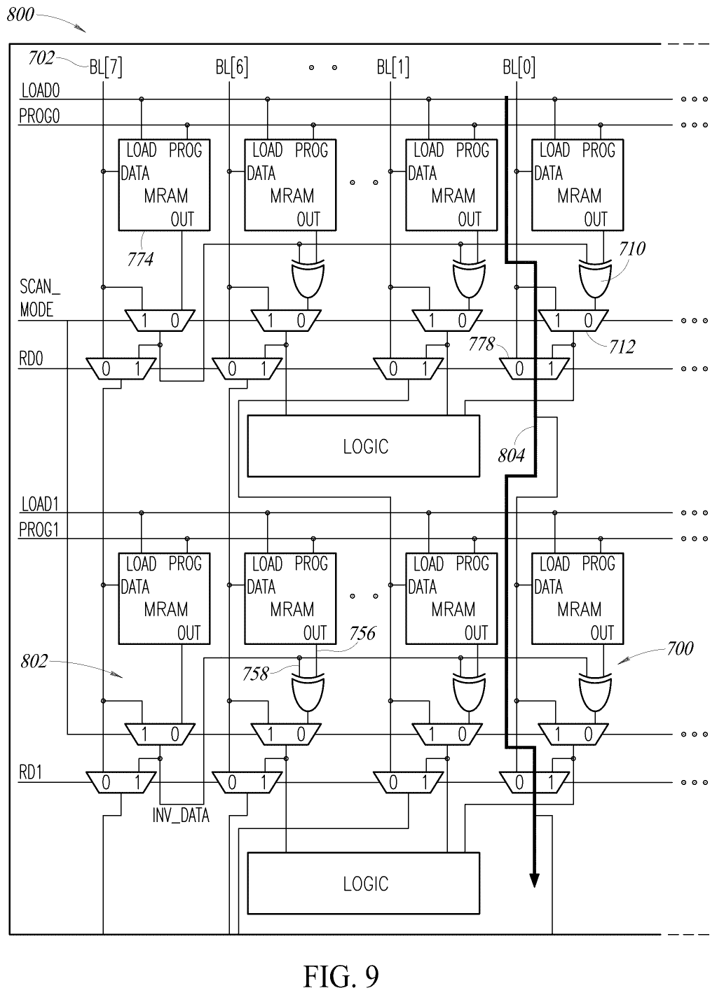

FIG. 9 is a system 800 including a plurality of circuits 700 of FIG. 8. More specifically, the system 800 includes a plurality of bit lines 702, each of which has a plurality of memory elements 774 coupled along it. FIG. 9 includes eight bit lines 702, labelled BL[7] through BL[0]. However, embodiments may include a different number of bit lines, for example, 16. Each bit line couples a plurality of configuration bits along a column of configuration bits.

The system 800 further includes a plurality of load lines LOAD0, LOAD1 coupled to a load input LOAD of each of the memory elements 774 and a plurality of programming lines PROG0, PROG1 coupled to a programming input PROG of each of the memory elements 774. A first load line LOAD0 and a first programming line PROG0 correspond to a first row of configuration bits and a second load line LOAD1 and a second programming line PROG1 correspond to a second row of configuration bits. The first plurality of logic components 722 of FIG. 8 has been omitted from FIG. 9 for simplicity.

Each configuration bit coupled along a first bit line BL[7] in the plurality of bit lines 702 is a protection bit 802. Each protection bit 802 does not include a third logic gate 710. Instead, an output OUT of the memory element 774 in each protection bit 802 is coupled directly to a first MUX 712.

Each configuration bit coupled along any bit line BL[6] through BL[0] of the plurality of bit lines 702 includes a third logic gate 710 coupled between the output OUT of the memory element 774 and the first MUX 712. A first input 756 of the third logic gate 710 is coupled directly to the output OUT of the memory element 774. A second input 758 of the third logic gate 710 is coupled to each third logic gate 710 of each configuration bit along an invert data line INV_DATA. The invert data line INV_DATA is coupled to an output of the first MUX 712 in the protection bit 802 and to a first input of a second MUX 778 in the protection bit 802.

Each first MUX 712 in each protection bit 802 and each regular circuit 700 includes a first input coupled to the memory element 774 and a second input coupled to each respective bit line 702. A scan enable input of each first MUX 712 is coupled to a scan mode signal SCAN_MODE.

The scan mode signal is a global signal throughout the entire device. It is related only to the circuit's activation in the test mode, where the memory element operation is being isolated in normal application-specific integrated circuit (ASIC) testing methodology.

Each second MUX 778 of each protection bit 802 and each regular circuit 700 has a first input coupled to an output of the first MUX 712, a second input coupled to the respective bit line 702, and a scan enable input coupled to one of the plurality of read lines RD0, RD1. A first read line RD0 corresponds to a first row of configuration bits and a second read line RD1 corresponds to a second row of configuration bits. The output of each first MUX 712 of each regular circuit 700 is coupled to a logic block LOGIC. The logic block LOGIC is common to each of the regular circuits 700 in a row, along bit lines BL[6] through BL[0] in FIG. 9. The output of each first MUX 712 of each protection bit 802 is coupled to each third logic gate 710 in each regular circuit 700 along the invert data line INV_DATA. An output of each second MUX 778 of each regular circuit 700 and each protection bit 802 is coupled to the respective bit line 702.

Since each bit line 702 is unidirectional, when multiple configuration bits are coupled along a bit line 702, each configuration bit requires an independent read signal and only one read signal can be activated at once. During the write mode, the second MUX 778 will select the bit line 702 output, which is the output of each second MUX 778. The bit line 702 output will drive the configuration data. Once the programming signal is activated along the programming lines PROG0, PROG1, the data will be written in the memory element 774.

During read back mode, only one read signal of one of the configuration bits will be activated. For the activated configuration bit, the second MUX 778 will select an output of the configuration bit as an input and the read data will propagate through each second MUX 778 of each sequential configuration bit, as shown by an arrow 804. The read data will be captured by a different set of BLSR, not shown in FIG. 9, downstream from the configuration bits.

FIGS. 10 and 11 demonstrate the function of a redundancy (protection) bit to repair a manufacturing defect in a cluster of configuration memory bits.

There are multiple causes of programming failure, including a bit being stuck at 0, a bit being stuck at 1, and a read/write failure due to defects in the transistor. While detection circuitry cannot discern the cause of a programming failure, it can detect that a failure has occurred. The implementation of detection circuitry has the flexibility to control the number of programming and readback attempts to support a successful redundancy repair. After the device has been programmed, if an error occurs, the data will be re-read to ensure that a read failure has not occurred before initiating a redundancy repair.

The redundancy repair routine includes programming non-inverting data with two consecutive reads followed by inverting the data with two consecutive reads. When a read passes, the programming routine moves on to the next groups of writing. Non-inverting writing is performed first, and if the readback data matches with the expected data, then the programming process moves on. However, if the readback data does not match the expected data, the cluster of configuration memory bits is reloaded with readback data and compared to the expected data a second time. If the intended data does not match the data during the second check, the inverting data must be programmed.

FIG. 10 depicts a simplified diagram showing the detection circuitry recording a failure. In this simplified example, there are five memory bits MRAM, where the first is a redundancy memory bit MRAM RED. The intended data ORIGINAL DATA, intended to be “01010,” is shifted into the word bit line shift register WBLSR. The first trial is a write operation, so an invert programming line prog_inv delivers an invert programming signal equal to zero. The invert programming signal is coupled to an input of each first logic gate 910, and since it is set to zero, the output of the plurality of first logic gates 910 is “01010,” which is written into the plurality of memory bits MRAM.

One of the plurality of memory bits MRAM is a stuck-at-1 bit 914, meaning that the output of a second logic gate 912 coupled to the stuck-at-1 bit 914 will read “1” instead of “0,” which is incorrect. The output of the plurality of second logic gates 912 is “1110,” where it should be “1010.”

FIG. 11 depicts a simplified diagram showing the detection circuitry recording a success. Following the recording of a failure, a rewrite will occur with inverted data, which is accomplished by setting the invert programming signal equal to one. Each of the plurality of first logic gates 910 will then invert the original data and the output of the plurality of first logic gates 910 is “10101,” which is written into the plurality of memory bits MRAM.

After the inversion of data, since the intended data for the stuck-at-1 bit 914 was “1,” the stuck bit value matches the input from the first plurality of logic gates 910. The outputs of the plurality of memory bits MRAM are inverted by the second plurality of logic gates 912. The output of the plurality of second logic gates 912 is “1010,” which matches with the original intended data.

The present disclosure includes a device comprising a bit line, a configuration bit coupled to the bit line, and a protection bit coupled to the configuration bit, the protection bit including a first logic gate coupled to the bit line, a second logic gate coupled to the first logic gate and to the bit line, a magnetoresistive memory circuitry coupled to the first logic gate and the second logic gate, the magnetoresistive memory circuitry including a non-volatile memory element and a latch, and a tri-gate coupled to the latch and to the bit line.

The configuration bit includes a third logic gate coupled to the bit line, a fourth logic gate coupled to the fourth logic gate and the bit line, a second magnetoresistive memory circuitry coupled to the third logic gate and the fourth logic gate, the magnetoresistive memory circuitry including a non-volatile memory element and a latch, a fifth logic gate coupled to the latch, a multiplexer (MUX) coupled to the fifth logic gate and the bit line, and a tri-gate coupled to the fifth logic gate, the MUX, and the bit line.

The first logic gate has a first input, a second input, and an output, the second input of the first logic gate being coupled to the bit line and the output of the first logic gate being coupled to the magnetoresistive memory circuitry. The second logic gate has a first input, a second input, and an output, the first input of the second logic gate being coupled to the first input of the first logic gate and the second input of the second logic gate being coupled to the bit line, the output being coupled to the magnetoresistive memory circuitry.

The first logic gate may be an AND gate. The second logic gate may be an AND gate and the second input of the second logic gate is inverted.

The first input of the first logic gate is coupled to a programming line. The tri-gate has an input coupled to the latch, an enable terminal coupled to a read line, and an output coupled to the bit line. The non-volatile memory element is a magnetic tunnel junction. A load line is directly coupled to the latch. An invert data line is coupled between the latch and the input of the tri-gate.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
a bit line;
a configuration bit coupled to the bit line;
a protection bit coupled to the configuration bit, the protection bit includes:
a first logic gate coupled to the bit line;
a second logic gate coupled to the first logic gate and to the bit line;
a magnetoresistive memory circuitry coupled to the first logic gate and the second logic gate, the magnetoresistive memory circuitry including a non-volatile memory element and a latch; and
a tri-gate coupled to the latch and to the bit line.

2. The device of claim 1, wherein the configuration bit includes:
a third logic gate coupled to the bit line;
a fourth logic gate coupled to the fourth logic gate and the bit line;
a second magnetoresistive memory circuitry coupled to the third logic gate and the fourth logic gate, the magnetoresistive memory circuitry including a non-volatile memory element and a latch;
a fifth logic gate coupled to the latch;
a multiplexer (MUX) coupled to the fifth logic gate and the bit line; and
a tri-gate coupled to the fifth logic gate, the MUX, and the bit line.

3. The device of claim 1, wherein the first logic gate has a first input, a second input, and an output, the second input of the first logic gate being coupled to the bit line and the output of the first logic gate being coupled to the magnetoresistive memory circuitry.

4. The device of claim 3, wherein the second logic gate has a first input, a second input, and an output, the first input of the second logic gate being coupled to the first input of the first logic gate and the second input of the second logic gate being coupled to the bit line, the output being coupled to the magnetoresistive memory circuitry.

5. The device of claim 1, wherein the first logic gate is an AND gate.

6. The device of claim 1, wherein the second logic gate is an AND gate and second input of the second logic gate is inverted.

7. The device of claim 3, wherein the first input of the first logic gate is coupled to a programming line.

8. The device of claim 1, wherein the tri-gate has an input coupled to the latch, an enable terminal coupled to a read line, and an output coupled to the bit line.

9. The device of claim 1, wherein the non-volatile memory element is a magnetic tunnel junction.

10. The device of claim 1, comprising a load line directly coupled to the latch.

11. The device of claim 1, comprising an invert data line coupled between the latch and the input of the tri-gate.

12. A system comprising:
a plurality of bit line shift registers;
a plurality of bit lines, each bit line coupled to one of the plurality of bit line shift registers;
a plurality of first logic components;
a plurality of second logic components;
a plurality of magnetoresistive memory circuits;
a plurality of configuration bits, each configuration bit coupled to one of the plurality of bit lines, each configuration bit including:
a first one of the plurality of first logic components coupled to a respective one of the plurality of bit lines;
a first one of the plurality of second logic components coupled to a respective one of the plurality of bit lines and to the first one of the plurality of first logic components; and
a first one of the plurality of magnetoresistive memory circuits coupled between the first one of the plurality of first logic components and the first one of the plurality of second logic components; and
a protection bit coupled to one of the plurality of bit lines, the protection bit including:
a second one of the plurality of first logic components coupled to a respective one of the plurality of bit lines; and
a second one of the plurality of magnetoresistive memory circuits coupled to the second one of the plurality of first logic components and the respective one of the bit lines.

13. The system of claim 12, comprising a first plurality of tri-gates, each first tri-gate coupled between a respective bit line shift register of the plurality of bit line shift registers and a respective bit line of the plurality of bit lines.

14. The system of claim 12, wherein:
each one of the plurality of first logic components comprises a first logic component of a first type and second logic component of the first type, both coupled directly to the respective bit line; and;
each one of the plurality of second logic components comprises a third logic component having a second type that is different than the first type, a multiplexer, and a second tri-gate.

15. The system of claim 12, wherein each one of the magnetoresistive memory circuits comprises a non-volatile memory element and a latch, each latch of each one of the magnetoresistive memory circuits being directly coupled to a load line.

16. The system of claim 15, comprising a word line shift register directly coupled to the load line, the load line being configured to deliver a load signal to each latch in each one of the magnetoresistive memory circuits.

17. The system of claim 15, wherein the latch in the protection bit is coupled directly to a third tri-gate.

18. A system, comprising:
a plurality of bit line shift registers each comprising a first multiplexer (MUX);
a first plurality of tri-gates, each including an input coupled to an output of one of the plurality of bit line shift registers and an output coupled to an input of the first MUX of each respective bit line shift register;
a plurality of bit lines, each bit line coupled to an output of one of the plurality of tri-gates;
a plurality of configuration bits, each configuration bit coupled to one of the plurality of bit lines; and
a protection bit coupled to one of the plurality of bit lines and to each of the plurality of configuration bits, the protection bit including:
a first logic gate coupled to the respective bit line;
a second logic gate coupled to the first logic gate and to the respective bit line;
a magnetoresistive memory circuitry coupled to the first logic gate and the second logic gate, the magnetoresistive memory circuitry including a non-volatile memory element and a latch; and
a second tri-gate coupled directly to the latch and to the respective bit line.

19. The system of claim 18, wherein each of the plurality of configuration bits includes:
a first plurality of logic components coupled to the respective bit line;
a magnetoresistive memory circuitry coupled to the first plurality of logic components, the magnetoresistive memory circuitry comprising a memory element and a latch; and
a third plurality of logic components coupled to the magnetoresistive memory circuitry and the respective bit line.

20. The system of claim 19, comprising a word line shift register (WLSR) coupled to each latch of the protection bit and each latch of each of the plurality of configuration bits.
